(19) United States
(12) Patent Application Publication
(10) Pub. No.: US 2025/0389492 A1
(43) Pub. Date: Dec. 25, 2025

(54) VARIABLE MASS PRESSURE-TEMPERATURE CONTROL UNIT AND METHOD TO IMPROVE COOLING AND ENERGY EFFICIENCY IN TWO-PHASE COOLING SYSTEMS

(71) Applicant: INTERNATIONAL BUSINESS MACHINES CORPORATION, ARMONK, NY (US)

(72) Inventors: FELIPE ANDRES VALENZUELA GAETE, POUGHKEEPSIE, NY (US); ALLAN CORY VANDEVENTER, POUGHKEEPSIE, NY (US); PHILIPP K. BUCHLING REGO, WAPPINGERS FALLS, NY (US); DUSTIN DEMETRIOU, HYDE PARK, NY (US)

(21) Appl. No.: 18/747,707

(22) Filed: Jun. 19, 2024

(51) Int. Cl. F28D 15/06; F28D 15/02; F28D 21/00

(52) U.S. Cl. CPC F28D 15/06; F28D 15/025; F28D 15/0266; F28D 2021/0029

(57) ABSTRACT

An apparatus for facilitating cooling of one or more electronic devices in a cooling system, the apparatus includes a first reservoir configured for containing a cooling medium of a cooling system, a variable mass mechanism coupled to the first reservoir, a pressure sensor for sensing a pressure value of a vapor side of the first reservoir, and a controller coupled to the pressure sensor and the variable mass mechanism. The controller is configured to control the variable mass mechanism to adjust a total mass of the cooling medium in the first reservoir in response to the pressure value to change an overall specific volume of the cooling system.

### BACKGROUND

The present disclosure relates to methods, apparatus, and products for a pressure-temperature control unit and method to improve cooling and energy efficiency in two-phase cooling systems.

### SUMMARY

According to embodiments of the present disclosure, various methods, apparatus and products for a pressure-temperature control unit and method to improve cooling and energy efficiency in two-phase cooling systems are described herein. In some aspects, a pressure-temperature control unit includes an apparatus for facilitating cooling of one or more electronic devices in a cooling system, the apparatus comprising: a first reservoir configured for containing a cooling medium of a cooling system; a variable mass mechanism coupled to the first reservoir; a pressure sensor for sensing a pressure value of a vapor side of the first reservoir; and a controller coupled to the pressure sensor and the variable mass mechanism, the controller configured to control the variable mass mechanism to adjust a total mass of the cooling medium in the first reservoir in response to the pressure value to change an overall specific volume of the cooling system.

In other aspects, a method includes receiving a pressure value of a vapor side of a first reservoir from a pressure sensor, the first reservoir configured for containing a cooling medium of a cooling system; and controlling a variable mass mechanism coupled to the first reservoir to adjust a total mass of the cooling medium in the first reservoir in response to the pressure value to change an overall specific volume of the cooling system.

In other aspects, a system includes a condenser; an evaporator coupled to the condenser; a pump coupled to the evaporator; a first reservoir having an inlet coupled to the condenser and an outlet coupled to the evaporator, the first reservoir configured for containing a cooling medium of a cooling system; a variable mass mechanism coupled to the first reservoir; a pressure sensor for sensing a pressure value of a vapor side of the first reservoir; and a controller coupled to the pressure sensor and the variable mass mechanism, the controller configured to control the variable mass mechanism to adjust a total mass of the cooling medium in the first reservoir in response to the pressure value to change an overall specific volume of the cooling system.

### BRIEF DESCRIPTION OF THE DRAWINGS

FIG. 1A sets forth an example conventional pumped two-phase cooling system.

FIG. 1B sets forth an example conventional thermosyphon two-phase cooling system.

FIG. 2 sets forth an example conventional pumped two-phase cooling system for cooling multiple electronic devices in parallel.

FIG. 3 sets forth an example pressure enthalpy (P-H) diagram illustrating the dual thermodynamic behavior of a pumped/thermosyphon two-phase cooling system.

FIG. 4 illustrates thermodynamic behavior of a pumped/thermosyphon two-phase system when specific volume is less than the critical specific volume.

FIG. 5 illustrates thermodynamic behavior of a pumped/thermosyphon two-phase system when specific volume is greater than the critical specific volume.

FIG. 6 sets forth an example pumped two-phase cooling system with a variable volume mechanism according to aspects of the present disclosure.

FIGS. 7A-7B set forth another example pumped two-phase cooling system with a variable volume mechanism according to aspects of the present disclosure.

FIG. 8 sets forth another example pumped two-phase cooling system with a variable volume mechanism according to aspects of the present disclosure.

FIGS. 9A-9B set forth another example pumped two-phase cooling system with a variable volume mechanism according to aspects of the present disclosure.

FIGS. 10A-10E set forth example variable volume reservoirs and associated variable volume mechanisms according to aspects of the present disclosure.

FIG. 11 sets forth a flowchart of an example process for facilitating cooling of one or more electronic devices in a cooling system according to aspects of the present disclosure.

FIG. 12 sets forth an example pumped two-phase cooling system with a variable mass mechanism according to aspects of the present disclosure.

FIG. 13 sets forth another example pumped two-phase cooling system with a variable mass mechanism according to aspects of the present disclosure.

FIG. 14 sets forth a flowchart of another example process for facilitating cooling of one or more electronic devices in a cooling system according to aspects of the present disclosure.

FIG. 15 sets forth an example computing environment according to aspects of the present disclosure.

### DETAILED DESCRIPTION

In two-phase cooling systems, heat is transferred from a heat generating component by evaporation and condensation of a cooling fluid or other cooling medium. In a pumped two-phase cooling system, the cooling fluid is transferred via pump. Typically, a liquid near saturation is pumped into an evaporator (e.g., a cold plate) thermally coupled to the heat generating component, and the liquid starts to boil thereby cooling the heat generating component and storing the energy in the latent heat of the fluid. The two-phase (i.e., liquid and vapor) fluid then flows to the condenser where the heat is removed from the fluid thereby condensing the vapor so that a single-phase liquid exits the condenser. The cycle then repeats. In a thermosyphon system, a density imbalance is generated between the evaporator and the condenser which circulates the fluid without the necessity of a mechanical pump.

Pumped/thermosyphon two-phase cooling systems are an efficient solution for cooling applications as they require minimal pumping power. This leads to a significant reduction in energy consumption when compared to single-phase cooling systems. However, since the refrigerant temperature and pressure are highly dependent on the ambient/heat-rejection temperature, there is no internal means to control the thermodynamic state of the system. Thus, the facility conditions govern the goal temperature and overall cooling efficiency.

Various aspects provide for a methodology and control unit configured to actively regulate the thermodynamic state of a pumped/thermosyphon two-phase cooling system. In an aspect the methodology adjusts the specific volume of the cooling system thereby enabling control of the overall system pressure and temperature independent of the ambient/heat-rejection conditions. In an aspect, a control unit includes a variable-volume reservoir/separator, a controller coupled to the variable-volume reservoir, and a pressure sensor to measure a pressure of the cooling medium of the cooling system. The controller receives the pressure measurement and adjusts the volume of the variable-volume reservoir to maintain the thermodynamic state (e.g., temperature and pressure) of the cooling system at a desired level. In an aspect, the control system improves the external energy efficiency as it decreases the pressure/temperature of the cooling system without increasing the pumping power of the heat-rejection coolant such as a fan power or facility water pumping power. This feature allows running of the heat-rejection coolant at a higher temperature without affecting the system pressure. Additionally, by actively controlling the overall specific volume of the system, the control unit raises the saturated liquid threshold thereby preventing over-pressurization and enhancing the reliability of the two-phase cooling system.

In an aspect, an in-rack temperature control unit to improve cooling and energy efficiency in pumped/thermosyphon two-phase cooling systems includes a control unit having a reservoir/separator with a variable-volume mechanism, a pressure sensor for sensing pressure on the vapor side of the reservoir/separator, and a controller coupled to the pressure sensor and the variable-volume mechanism. The controller controls the reservoir/separator total volume to change the overall specific volume and control the system thermodynamic state and/or move the saturated liquid threshold at a desired level.

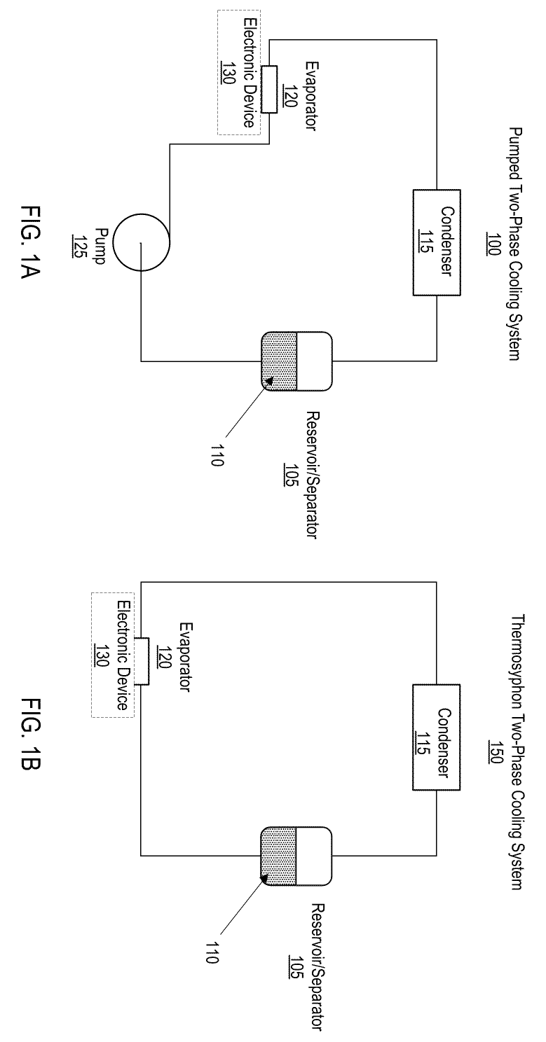

With reference now to the figures, FIG. 1A sets forth an example conventional pumped two-phase cooling system 100. The pumped two-phase cooling system 100 includes a reservoir/separator 105 configured to contain a portion of a cooling medium 110 of the pumped two-phase cooling system 100. The reservoir/separator 105 has a fluid outlet having fluid coupling to a fluid inlet of a pump 125. The pump 125 facilitates circulation of the cooling medium within the pumped two-phase cooling system 100 and has a fluid outlet coupled to an inlet of an evaporator 120. The evaporator 120 is thermally coupled to an electronic device 130 that is cooled by the two-phase cooling system 100 during operation of the electronic device 130. In some aspects, the electronic device 130 includes a processor, memory, or any other heat-generating electronic component. The evaporator has a fluid outlet having a fluid coupling to a fluid inlet of a condenser 115. The condenser 115 has a fluid outlet having a fluid coupling to a fluid inlet of the reservoir/separator 105.

During operation of the pumped two-phase cooling system 100, the pump 125 circulates the cooling medium 110 from the reservoir/separator 105, through the evaporator 120, and into the condenser 115. The evaporator 120 receives heat generated by the electronic device 130 and transfers the heat to the cooling medium 110 flowing through the evaporator 120 which causes a portion of the cooling medium 110 to transition from a liquid phase to a vapor phase. The condenser 115 receives the cooling medium 110 which extracts the heat from the cooling medium and causes the cooling medium to condense to the liquid phase. After condensation, the medium 110 flows into the reservoir/separator 105 which contains portions of the cooling medium 110 in a liquid phase and the vapor phase mixture. The liquid phase portion of the cooling medium 110 flows into the pump 110 which circulates the cooling medium 110 through evaporator 120. In particular embodiments, the condenser 115 is air-cooled and/or liquid cooled to facilitate extraction of the heat from the cooling medium 110.

With reference now to FIG. 1B, FIG. 1B sets forth an example conventional thermosyphon two-phase cooling system 150. The thermosyphon two-phase cooling system 150 includes the reservoir/separator 105, cooling medium 110, condenser 115, evaporator 120, and electronic device 130 of FIG. 1A. In contrast to the pumped two-phase cooling system 100 of FIG. 1A, the thermosyphon two-phase cooling system 150 of FIG. 1B does not include the pump 125 to circulate the cooling medium 110. Instead, the thermosyphon two-phase cooling system 150 relies on buoyancy forces due to the density imbalance between the downflow and upflow columns to circulate the cooling medium 110 through the thermosyphon two-phase cooling system 150 in order to cool the electronic device 130.

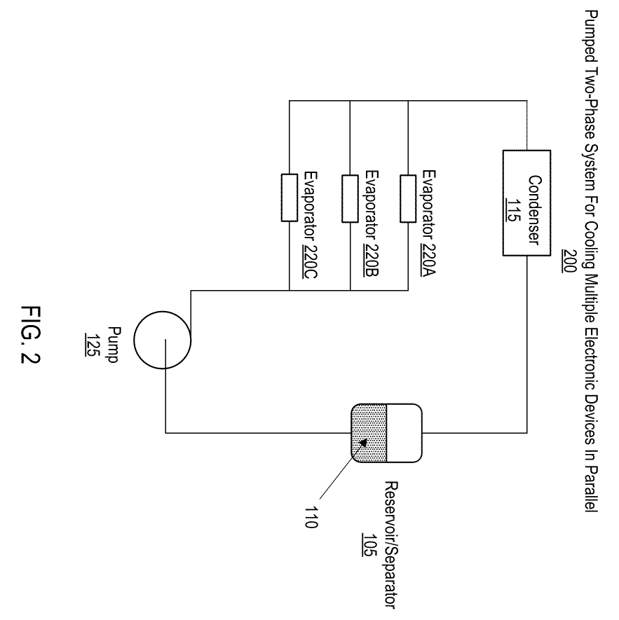

With reference now to FIG. 2, FIG. 2 sets forth an example conventional pumped two-phase cooling system 200 for cooling multiple electronic devices in parallel. The pumped two-phase cooling system 200 includes the reservoir/separator 105, cooling medium 110, condenser 115, and pump 125 of FIG. 1A. Instead of the single evaporator 120 of FIG. 1A, the pumped two-phase cooling system 200 of FIG. 2 includes multiple evaporators 220A, 220B, and 220C connected in parallel for cooling multiple electronic devices (not shown). Accordingly, the flow of the cooling medium 110 is split and provided in parallel to each of the evaporators 220A-220C and merged after passing through the evaporators 220A-220C and provided to condenser 115 and into the reservoir/separator 105.

Each of the cooling systems of FIGS. 1A-1B and FIG. 2 are constant volume and constant mass systems. That is, in each of the cooling systems, the volume (V sys) and the mass (M ref) of the cooling medium 110 within the cooling system remain constant. The ratio of the volume V systo the mass M ref is referred to as the specific volume (v) of the cooling system and is given by the equation: v= V sys/M ref. In each of the cooling systems of FIGS. 1A-1B and FIG. 2, the specific volume v is a constant. The value of the specific volume v has a significant effect upon the performance of the cooling system and further described below.

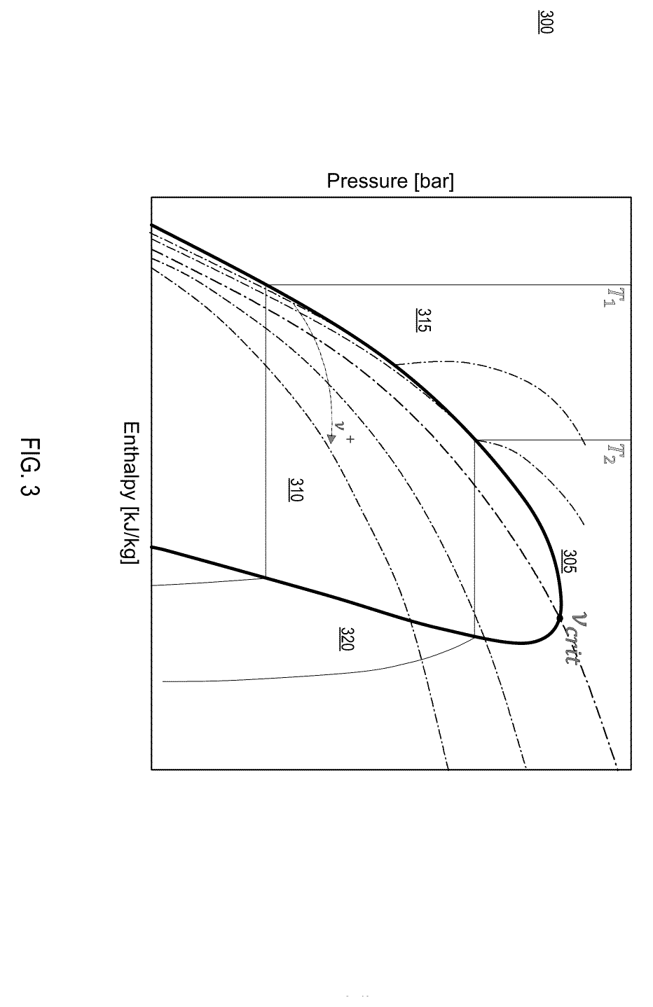

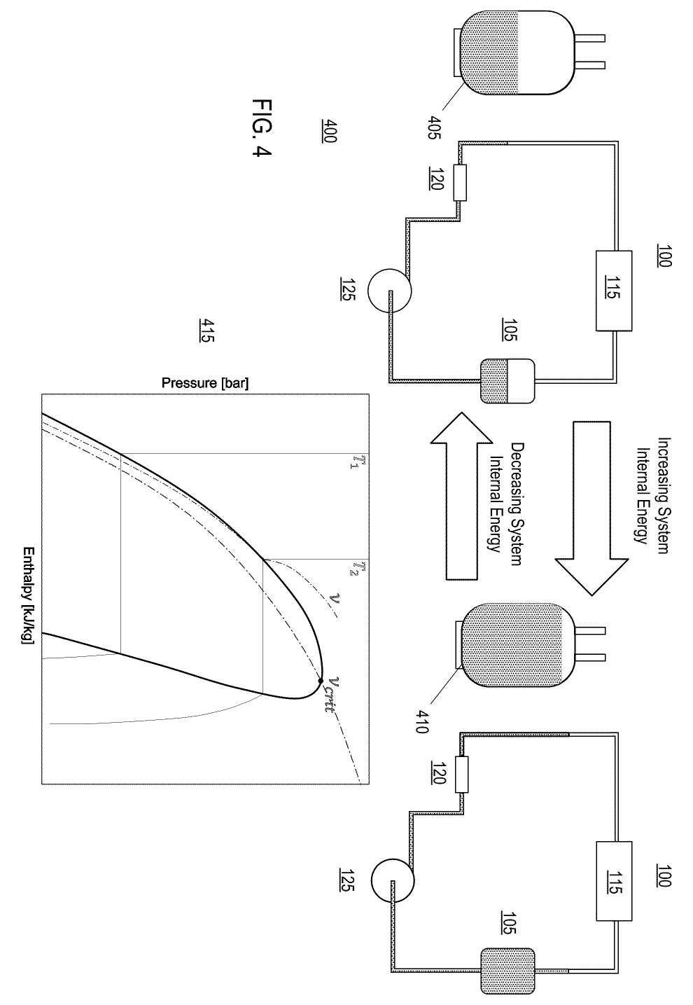

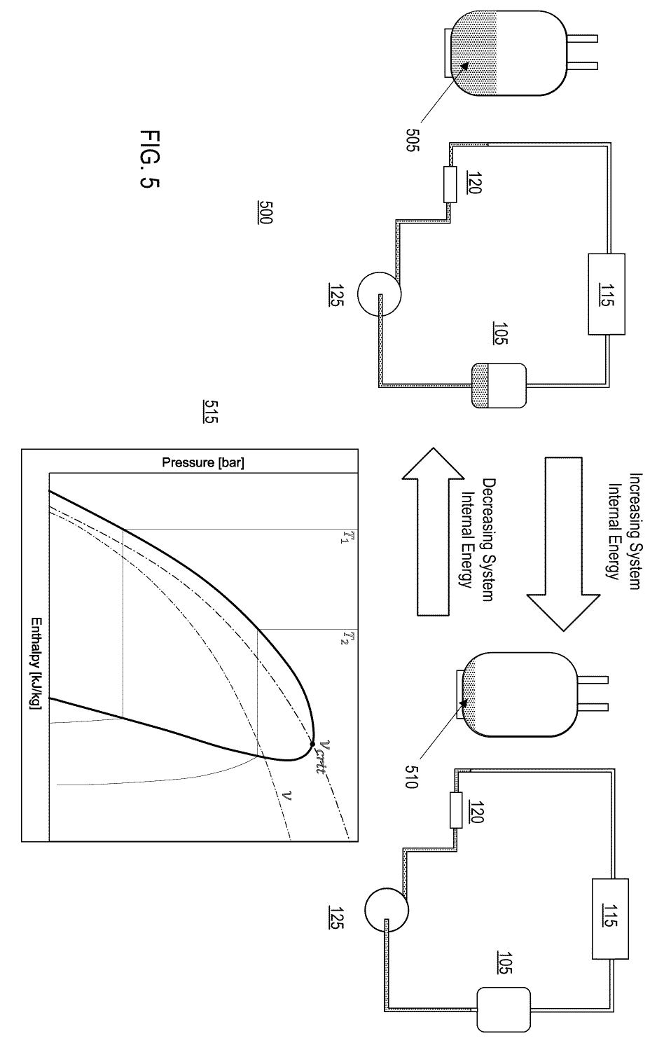

FIG. 3 sets forth an example pressure enthalpy (P-H) diagram 300 illustrating the dual thermodynamic behavior of a pumped/thermosyphon two-phase cooling system. The P-H diagram 300 indicates pressure on the y-axis and enthalpy on the x-axis. The upside down U-shaped solid line 305 designates the points at which the cooling medium 110 changes phase. The left side of the vertical curve shown in the solid line 305 indicates the saturated liquid curve and the right side of the vertical curve shown in the solid line 305 indicates the saturated vapor curve. The region 310 between the two curves describe cooling medium states that contain a mixture of both liquid and vapor and is referred to as the liquid-vapor mix region. The region 315 to the left of the saturated liquid curve indicates that the cooling medium 110 is in liquid form, and the region 320 to the right of the saturated vapor curve indicate that the cooling medium 110 is in vapor form. The point at which two curves meet is referred to as the critical point. The dashed upward sloping lines represent constant specific volume (v) lines. The dual thermodynamic behavior of the pumped/thermosyphon two-phase cooling system depends on specific volume v being higher or lower than the critical specific volume (v crit) as further described with reference to FIGS. 4 and 5 below.

FIG. 4 illustrates thermodynamic behavior 400 of a pumped/thermosyphon two-phase system when specific volume is less than the critical specific volume. FIG. 4 illustrates the thermodynamic behavior of the pumped two-phase cooling system of FIG. 1A and an associated P-H diagram 415 when v= V sys/M ref < v crit. As the system internal energy increases, i.e., increasing ambient temperature (e.g., an air-cooled condenser)/coolant temperature (e.g., a liquid-cool condenser) and/or heat input at the evaporator), the volume of the liquid phase of the cooling medium 110 increases 410. As the system internal energy decreases, i.e., decreasing ambient temperature (e.g., an air-cooled condenser)/coolant temperature (e.g., a liquid-cool condenser) and/or heat input at the evaporator), the volume of the liquid phase of the liquid phase of the cooling medium 110 decreases 405. When the v curve (dash dot line) reaches the liquid line, the cooling system is full of liquid. However, to avoid over-pressurization and provide effective cooling a mixture of liquid phase and vapor phase of the cooling medium is required within the cooling system.

FIG. 5 illustrates thermodynamic behavior 500 of a pumped/thermosyphon two-phase system when specific volume is greater than the critical specific volume. FIG. 5 illustrates the thermodynamic behavior of the pumped two-phase cooling system of FIG. 1A and an associated P-H diagram 515 when v= V sys/M ref > v crit. As the system internal energy increases, i.e., increasing ambient temperature (e.g., an air-cooled condenser)/coolant temperature (e.g., a liquid-cool condenser) and/or heat input at the evaporator), the volume of the liquid phase of the cooling medium 110 decreases 510. As the system internal energy decreases, i.e., decreasing ambient temperature (e.g., an air-cooled condenser)/coolant temperature (e.g., a liquid-cool condenser) and/or heat input at the evaporator), the volume of the liquid phase of the liquid phase of the cooling medium 110 increases 505. When the v curve (dash dot line) reaches the vapor line, the cooling system is full of vapor. However, to avoid system dry-out and provide effective cooling a mixture of liquid phase and vapor phase of the cooling medium is required within the cooling system.

For a pumped two-phase cooling system, controlling the thermodynamic state should allow for the absorption of any energy increase and corresponding pressure increase. However, air should not be allowed inside the cooling system since it will change the thermodynamic properties of the coolant and thus the thermal behavior of the system. To allow expansion inside the system, a vapor-liquid mixture should exist at any point in time and under any operating conditions (e.g., ambient conditions and under a workload). Additionally, the control system should constantly ensure sufficient pressure for the pump and sufficient liquid-phase coolant in the supply line.

Various implementations avoid over-pressurization or drying out of the system reservoir by controlling the specific volume via control of v= V sys/M ref. Some volume of the system should be occupied by the cooling medium (e.g., refrigerant) vapor phase to absorb any expansion of the liquid phase. If the system is full of an incompressible liquid, the pressure will rapidly increase thereby inducing a system over-pressurization. Over-pressurization prevents the normal operation of the two-phase system and may result in high subcooling and a dangerous high pressure in the cooling system. In addition, a certain liquid level (e.g., height) should be kept within the reservoir to ensure proper pump operation.

Various implementations described herein provide for a methodology, control unit, apparatus, and system configured to control the overall system pressure of a cooling system by adjusting the specific volume of the cooling system such that v is controlled by adjusting V sys. This enables control of the overall system thermodynamic state independent of the ambient/heat-rejection conditions of the control system. Various implementations provide for controlling the thermodynamic state of the whole cooling system instead of trying to control the thermodynamic state at different points in the system with an in-line device as any inline pressure control device only adds to the total pressure delta of the system. In a particular implementation, a control unit includes a reservoir/separator including a variable-volume mechanism, a pressure sensor for sensing pressure on the vapor side of the reservoir/separator, and a controller coupled to the pressure sensor and the variable-volume mechanism. In an implementation, the controller controls the reservoir/separator total volume to change the overall specific volume of the cooling medium and thereby control the system thermodynamic state or move the saturated liquid threshold at a desired level.

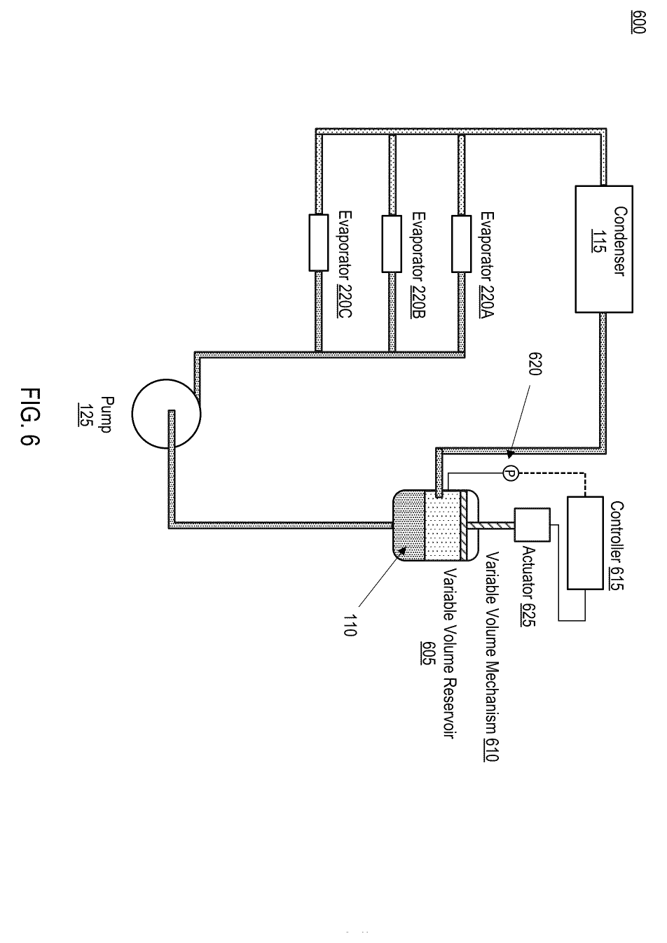

FIG. 6 sets forth an example pumped two-phase cooling system 600 with a variable volume mechanism according to aspects of the present disclosure. The pumped two-phase cooling system 600 includes a variable volume reservoir 605 containing a cooling medium 110 having a predetermined mass M ref. In a particular implementation the value of M ref is chosen to keep the specific volume v<v crit. An outlet of the variable volume reservoir 605 is coupled to an inlet of a pump 125. An outlet of the pump 125 is coupled to inlets of multiple, parallel evaporators 220A, 220B, 220C. The evaporators 220A, 220B, 220C are configured to cool one or more heat generating electronic components (not shown). Outlets of the evaporators 220A, 220B, and 220C are coupled to an inlet of a condenser 115. An outlet of the condenser 115 is coupled to an inlet of a variable volume reservoir 605.

The pumped two-phase cooling system 600 also includes a variable volume mechanism 610 coupled to the variable volume reservoir 605. The variable volume mechanism 610 is configured to vary the internal volume of the variable volume reservoir 605 in response to a control signal from a controller 615. The pumped two-phase cooling system 600 further includes a pressure sensor 620 configured to measure a pressure of the vapor phase of the variable volume reservoir 605 and provide the pressure measurement to the controller 615. In the particular embodiment, the variable volume mechanism 610 comprises a piston within the variable volume reservoir 605 mechanically coupled to an actuator 625.

In response to the pressure measurement, the controller 615 controls the actuator 625 to move the variable volume mechanism 610 to either increase or decrease the volume of the variable volume reservoir 605. The pressure for a given specific volume defines how close the thermodynamic state of the cooling system is to the saturated liquid curve. Accordingly, the controller 615 utilizes the pressure measurement to determine how V sys should be adjusted to achieve a desired specific volume v while M ref remains substantially constant. In a particular implementation, the actuator 625 is configured to move the piston within the variable volume reservoir 605 in response to a signal from the controller 615. By varying the volume of the variable volume reservoir 605, the variable volume mechanism 610 changes the value of V sys, thus changing the specific volume v in accordance with the equation v= V sys/M ref to maintain the pumped two-phase cooling system 600 within the desired thermodynamic state. For example, if it is desired to increase the value of the specific volume v, the controller 615 controls the actuator 625 to increase the volume of the variable volume reservoir 605. Conversely, if it is desired to decrease the value of the specific volume v, the controller 615 controls the actuator 625 to decrease the volume of the variable volume reservoir 605. It is desirable to change the volume of the cooling medium 110 without “compressing” the liquid phase. Various implementations described herein avoid applying external/fictitious pressure to the cooling system, and in particular the inlet of pump 125.

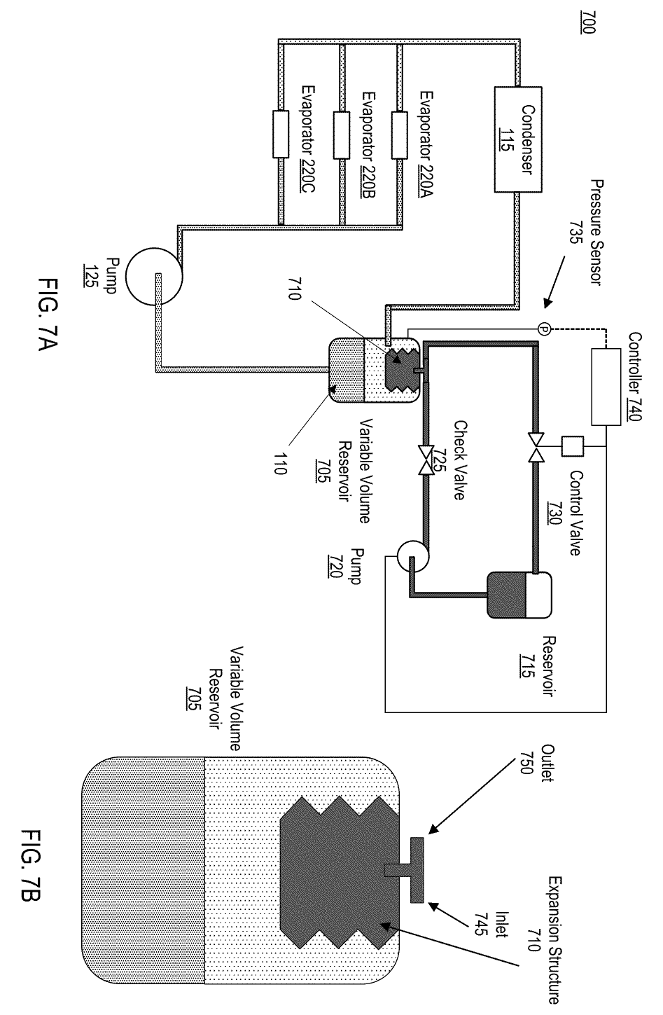

FIGS. 7A-7B set forth another example pumped two-phase cooling system 700 with a variable volume mechanism according to aspects of the present disclosure. In the example of FIGS. 7A-7B, the two-phase system pressure of the pumped two-phase cooling system 700 is greater than the ambient pressure outside of the cooling system. The pumped two-phase cooling system 700 includes a variable volume reservoir 705 containing a cooling medium 110. The pumped two-phase cooling system 700 also includes a condenser 115, multiple evaporators 220A, 220B, and 220C connected in parallel for cooling one or more electronic devices (not shown), and a pump 125 arranged in the manner described with respect to FIG. 6. An outlet of the pump 125 is coupled to an inlet of the evaporators 220A, 220B, and 220C. An outlet of the evaporators 220A, 220B, and 220C is coupled to an inlet of the condenser 115. An outlet of the condenser is coupled to an inlet of the variable volume reservoir 705. An outlet of the variable volume reservoir 705 is coupled to an inlet of the pump 125.

The pumped two-phase cooling system 600 also includes an expansion structure 710 within the variable volume reservoir 705 functioning as a variable volume mechanism. The expansion structure 710 is configured to expand or retract within the variable volume reservoir 705 to vary the internal volume of the variable volume reservoir 705 in response to a control signal from a controller 740. In the particular embodiment illustrated in FIGS. 7A-7B, the expansion structure 710 includes a bellow structure configured to either be inflated to decrease the volume of the variable volume reservoir 705 or deflated to decrease the volume of the variable volume reservoir 705. The pumped two-phase cooling system 700 further includes a pressure sensor 735 configured to measure a pressure of the vapor phase of the variable volume reservoir 705 and provide the pressure measurement to the controller 740.

The pumped two-phase cooling system 700 also includes a control valve 730 having an outlet that is coupled to a secondary reservoir 715 holding an incompressible fluid. An outlet of the secondary reservoir 715 is coupled to an inlet of a pump 720 which includes an outlet coupled to a check valve 725. The check valve 725 is coupled to an inlet 745 of the expansion structure 710 and an outlet 750 of the expansion structure 710 is coupled to an inlet of the control valve 730. The operation of the pump 720 is under control of the controller 740.

In response to the pressure measurement, the controller 740 controls the expansion structure 710 to either increase or decrease the volume of the variable volume reservoir 705. In order to decrease the volume of the variable volume reservoir 705, the controller expands the expansion structure 710 within the reservoir 705 by closing the control valve 730 and activating the pump 720 to pump the fluid from the secondary reservoir 715 into the expansion structure 710 until the desired amount of volume decrease within the variable volume reservoir 705 is achieved. When the desired amount of volume decrease is reached, the controller 740 ceases operation of the pump 720. The check valve 725 prevents backflow of the fluid from expansion structure 710 towards the pump 720. The desired amount of expansion is maintained within the expansion structure. In order to increase the volume of the variable volume reservoir 705, the controller 740 reduces the volume of the expansion structure 710 by opening the control valve thereby enabling fluid to flow from the expansion structure through the control valve 730 into the secondary reservoir 715. When the desired amount of retraction is reached, the controller 740 closes the control valve 730.

By varying the volume of the variable volume reservoir 705, the expansion structure changes the value of V sys, thus changing the specific volume v in accordance with the equation v= V sys/M ref to maintain the pumped two-phase cooling system 700 within the desired thermodynamic state. For example, if it is desired to increase the value of the specific volume v, the controller 740 controls the pump 720 and the control valve 730 to increase the volume of the variable volume reservoir 705. Conversely, if it is desired to decrease the value of the specific volume v, the controller 740 controls the pump 720 and the control valve 730 to decrease the volume of the variable volume reservoir 705.

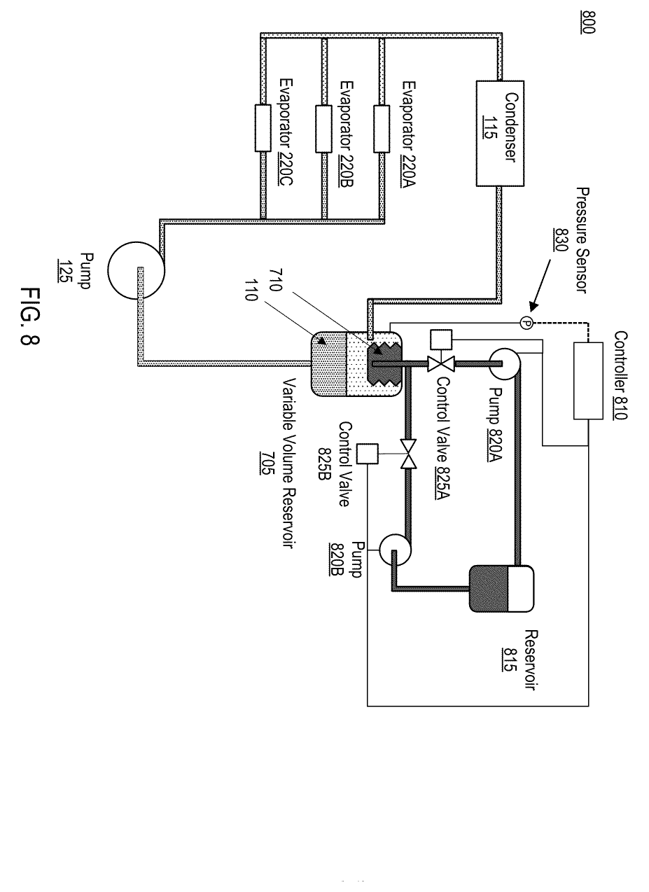

FIG. 8 sets forth another example pumped two-phase cooling system 800 with a variable volume mechanism according to aspects of the present disclosure. In the example of FIG. 8, the two-phase system pressure of the pumped two-phase cooling system 800 is less than the ambient pressure outside of the cooling system. The pumped two-phase cooling system 800 includes a variable volume reservoir 705 containing a cooling medium 110. The pumped two-phase cooling system 800 further includes a condenser 115, multiple evaporators 220A, 220B, and 220C connected in parallel for cooling one or more electronic devices (not shown), and a pump 125 arranged in the manner described with respect to FIG. 6. An outlet of the pump 125 is coupled to an inlet of the evaporators 220A, 220B, and 220C.

The pumped two-phase cooling system 800 also includes an expansion structure 710 within the variable volume reservoir 705 functioning as a variable volume mechanism. The expansion structure 710 is configured to expand or retract within the variable volume reservoir 705 to vary the internal volume of the variable volume reservoir 705 in response to control signals from a controller 810. In the particular embodiment illustrated in FIG. 8, the expansion structure 710 includes a bellow structure configured to either be inflated to decrease the volume of the variable volume reservoir 705 or deflated to decrease the volume of the variable volume reservoir 705. The pumped two-phase cooling system 800 further includes a pressure sensor 830 configured to measure a pressure of the vapor phase of the variable volume reservoir 705 and provide the pressure measurement to the controller 810.

The pumped two-phase cooling system 800 further includes a secondary reservoir 815 holding an incompressible fluid. An inlet of the secondary reservoir 815 is coupled to an outlet of a first pump 820A having an inlet coupled to an outlet of a first control valve 825A. An inlet of the first control valve 825A is coupled to an outlet of the expansion structure 710. An inlet of the expansion structure 710 is coupled to an outlet of a second control valve 825B. An inlet of the second control valve 825B is further coupled to an outlet of a second pump 820B. An inlet of the second pump 820B is coupled to an outlet of the secondary reservoir 815. The operation of the first pump 820A, the first control valve 825A, the second pump 820B, and the second control valve 825B are under control of the controller 810.

In response to the pressure measurement, the controller 810 controls the expansion structure 710 to either increase or decrease the volume of the variable volume reservoir 705. In order to decrease the volume of the variable volume reservoir 705, the controller 810 expands the expansion structure 710 by opening the second control valve 825B, closing the first control valve 825A, and activating the second pump 820B to pump the fluid from the secondary reservoir 815 into the expansion structure 710 until the desired amount of volume decrease within the variable volume reservoir 705 is achieved. When the desired amount of volume increase is reached, the controller 810 closes the second control valve 825B and turns off the second pump 820B. In order to increase the volume of the variable volume reservoir 705, the controller 810 contracts the expansion structure 710 by opening the first control valve 825A, closing the second control valve 825B, and activating the first pump 820A to pump fluid from the expansion structure into the secondary reservoir 815 until the desired amount of contraction of the expansion structure 710 is reached. When the desired amount of contraction is reached, the controller 810 closes the first control valve 825A and turns off the first pump 820A.

By varying the volume of the variable volume reservoir 705, the expansion structure changes the value of V sys, thus changing the specific volume v in accordance with the equation v= V sys/M ref to maintain the pumped two-phase cooling system 800 within the desired thermodynamic state. For example, if it is desired to increase the value of the specific volume v, the controller 810 controls the first pump 820A, the first control valve 825A, the second pump 820B, and the second control valve 825B to increase the volume of the variable volume reservoir 705. Conversely, if it is desired to decrease the value of the specific volume v, the controller 810 controls the first pump 820A, the first control valve 825A, the second pump 820B, and the second control valve 825B to decrease the volume of the variable volume reservoir 705.

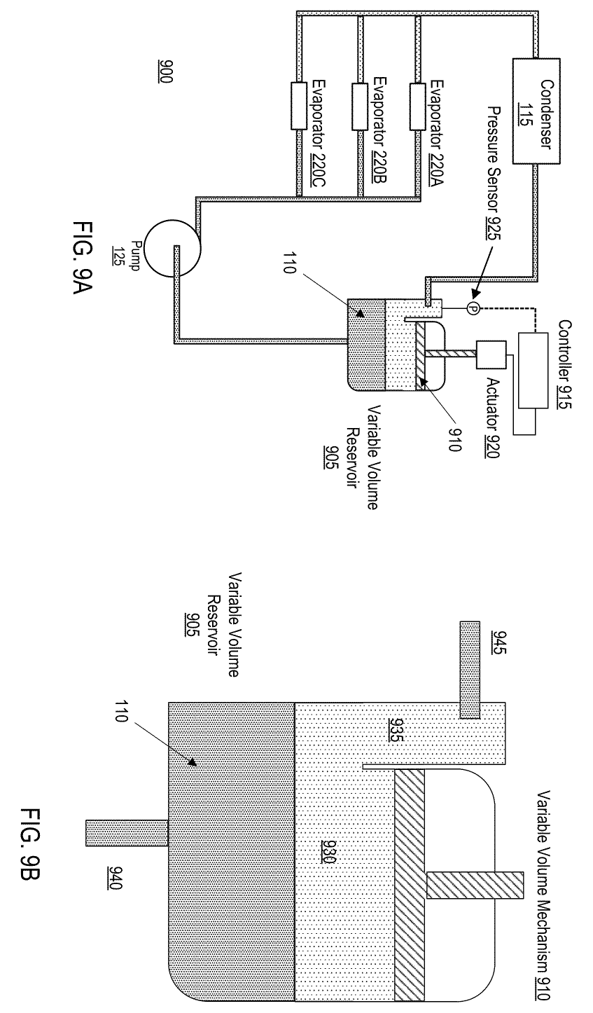

FIGS. 9A-9B set forth another example pumped two-phase cooling system 900 with a variable volume mechanism according to aspects of the present disclosure. The pumped two-phase cooling system 900 includes a variable volume reservoir 905 containing a cooling medium 110. An inlet 945 of the variable volume reservoir 905 is coupled to an outlet of a condenser 115, and an inlet of the condenser 115 is coupled to respective outlets of multiple evaporators 220A, 220B, and 220C connected in parallel for cooling one or more electronic devices (not shown). Inlets of the evaporators 220A, 220B, and 220C are coupled to an outlet of a pump 125. An inlet of the pump 125 is coupled to an outlet 940 of the variable volume reservoir 905. The pumped two-phase cooling system 900 also includes a variable volume mechanism 910 coupled to the variable volume reservoir 905. The variable volume mechanism 910 is configured to vary the internal volume of the variable volume reservoir 905 in response to a control signal from a controller 915. The pumped two-phase cooling system 900 further includes a pressure sensor 925 configured to measure a pressure of the vapor phase of the variable volume reservoir 905 and provide the pressure measurement to the controller 915. In the particular embodiment, the variable volume mechanism 910 comprises a piston within the variable volume reservoir 905 mechanically coupled to an actuator 920.

The variable volume reservoir 905 includes a primary chamber 930 coupled to an inlet manifold 935. The variable volume mechanism 910 is configured to move within the primary chamber 930 to change the overall volume within the variable volume reservoir 905. The inlet manifold 935 extends into a middle portion of the primary chamber 930 to allow greater movement of the variable volume mechanism 910 without blocking the inlet 945.

In response to the pressure measurement, the controller 915 controls the actuator 920 to move the variable volume mechanism 910 to either increase or decrease the volume of the variable volume reservoir 905. By varying the volume of the variable volume reservoir 905, the variable volume mechanism 910 changes the value of V sys, thus changing the specific volume v in accordance with the equation v= V sys/M ref to maintain the pumped two-phase cooling system 900 within the desired thermodynamic state. For example, if it is desired to increase the value of the specific volume v, the controller 915 controls the actuator 920 to increase the volume of the variable volume reservoir 905. Conversely, if it is desired to decrease the value of the specific volume v, the controller 915 controls the actuator 920 to decrease the volume of the variable volume reservoir 905.

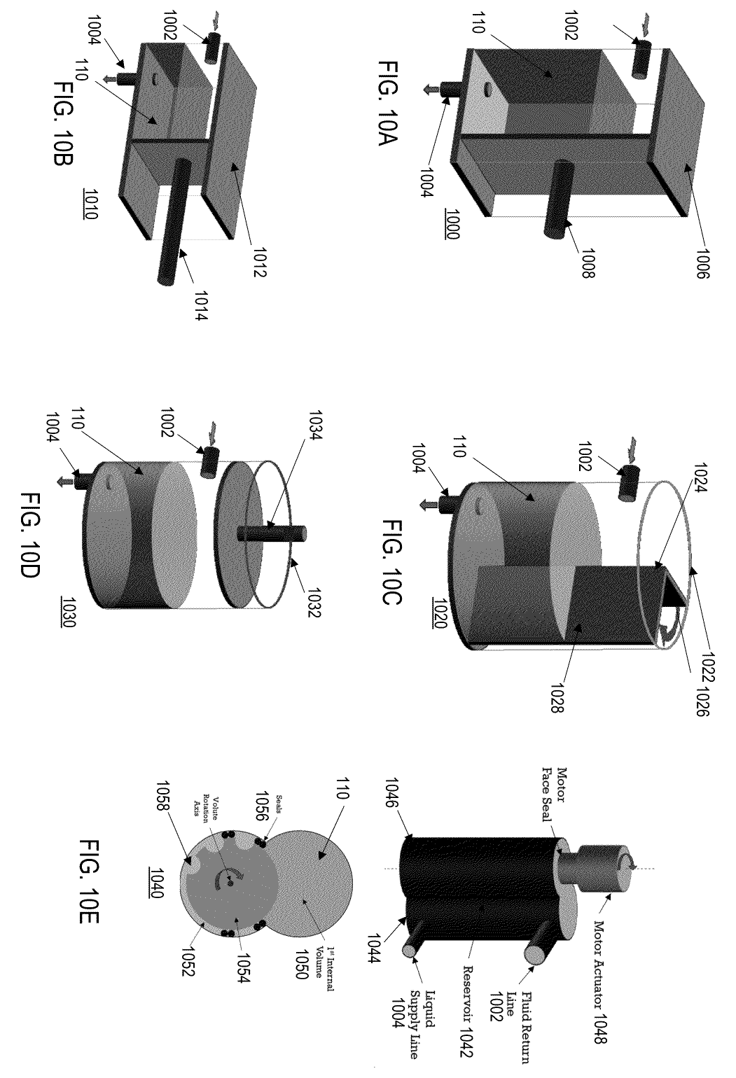

FIGS. 10A-10E set forth example variable volume reservoirs and associated variable volume mechanisms according to aspects of the present disclosure. FIG. 10A shows an example variable volume reservoir 1000 having a fluid chamber 1006 containing cooling medium 110. The fluid chamber 1006 includes an inlet 1002 and an outlet 1004. The variable volume reservoir 1000 includes a variable volume mechanism 1008 in the form of a piston with a rectangular face for changing the volume within the fluid chamber 1006. FIG. 10B shows another example variable volume reservoir 1010 having a fluid chamber 1012 containing cooling medium 110. The fluid chamber 1012 includes an inlet 1002 and an outlet 1004. The variable volume reservoir 1010 includes a variable volume mechanism 1014 in the form of a piston with a square face for changing the volume within the fluid chamber 1012. FIG. 10C shows another example variable volume reservoir 1020 having a fluid chamber 1022 containing cooling medium 110. The fluid chamber 1022 includes an inlet 1002 and an outlet 1004. The variable volume reservoir 1020 includes a variable volume mechanism 1024 having a fixed portion 1026 and a rotating portion 1028. The rotating portion 1028 rotates with respect to the fixed portion 1026 to change the volume within the fluid chamber 1022.

FIG. 10D shows another example variable volume reservoir 1030 having a cylindrical fluid chamber 1032 containing cooling medium 110. The fluid chamber 1032 includes an inlet 1002 and an outlet 1004. The variable volume reservoir 1030 includes a variable volume mechanism 1034 in the form of a piston with a circular face for changing the volume within the fluid chamber 1032. FIG. 10E shows another example variable volume reservoir 1040 having a fluid chamber 1042 containing cooling medium 110. The fluid chamber 1042 is divided into a primary portion 1044 and a secondary portion 1046. The primary portion 1044 includes a first internal volume 1050, and the secondary portion includes a second internal volume 1052. The secondary portion 1046 further includes a rotatable structure 1054 functioning as a variable volume mechanism mechanically coupled to a motor actuator 1048. The rotatable structure is sealed from the primary portion 1044 via seals 1056 and includes a number of grooves 1058 in a sidewall. The motor actuator 1048 is configured to rotate the rotatable structure 1054 about a rotation axis to either rotate one or more of the groves 1058 in contact with the first internal volume 1050 of the primary portion 1044 to either increase or decrease the volume of the fluid chamber 1042. The primary portion 1044 further includes an inlet 1002 coupled to a fluid return line and an outlet 1004 coupled to a liquid supply line towards the pump.

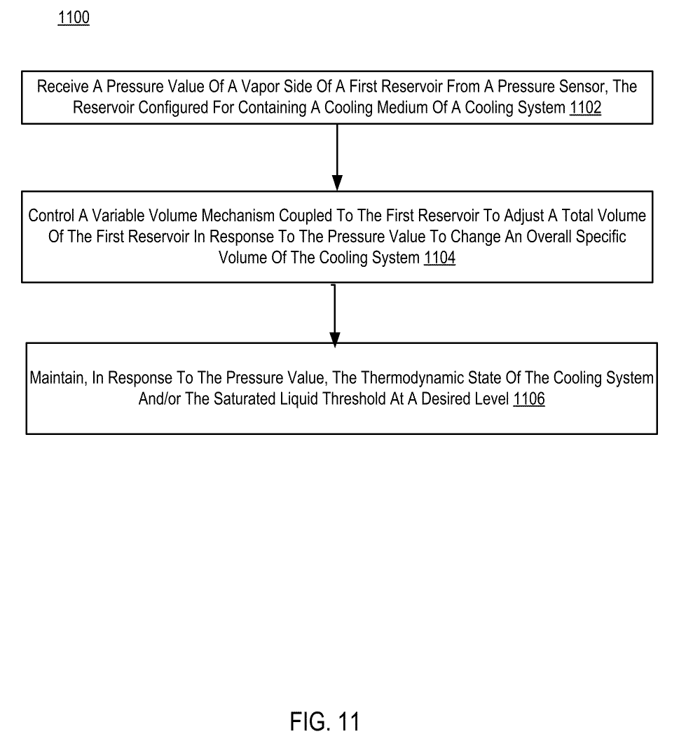

FIG. 11 sets forth a flowchart of an example process 1100 for facilitating cooling of one or more electronic devices in a cooling system according to aspects of the present disclosure. The example process 1100 includes receiving 1102 a pressure value of a vapor side of a reservoir from a pressure sensor. The reservoir is configured for containing a cooling medium of a cooling system. The example process further includes controlling 1104 a variable-volume mechanism coupled to the reservoir to adjust a total volume of the reservoir in response to the pressure value to change an overall specific volume of the cooling system.

In an aspect, the change in the overall specific volume of the cooling medium of the cooling system adjusts a thermodynamic state of the cooling system and/or moves the saturated liquid threshold at a desired level. In another aspect, the variable volume mechanism comprises a piston within the first reservoir, and adjusting the total volume of the first reservoir includes moving the piston within the first reservoir. In another aspect, the variable volume mechanism includes an expansion structure within the first reservoir, and wherein adjusting the total volume of the first reservoir comprises expanding or retracting the expansion structure within the first reservoir. In an aspect, the example process 1100 optionally includes maintaining 1106, in response to the pressure value, the thermodynamic state of the cooling system and/or moves the saturated liquid threshold at a desired level.

In other aspects, the specific volume of a cooling system is adjusted by changing (i.e., increasing or decreasing) the mass of the cooling medium in the cooling system. In a particular implementation, a control unit includes a reservoir/separator including a variable mass mechanism, a pressure sensor for sensing pressure on the vapor side of the reservoir/separator, and a controller coupled to the pressure sensor and the variable mass mechanism. In an aspect, the controller controls the variable mass mechanism to change the mass M ref of the cooling medium within the cooling system. In an aspect, the value of V sys is chosen to be a predetermined value and remains substantially constant. As a result, the overall specific volume v of the cooling medium is changed according to the equation v= V sys/M ref and thereby controlling the system thermodynamic state or move the saturated liquid threshold at a desired level. For example, to increase the specific volume v, the variable mass mechanism extracts cooling fluid from the cooling system to lower the mass M ref of the cooling fluid within the cooling system. In contrast, to decrease the specific volume v, the variable mass mechanism increases the cooling fluid within the cooling system to increase the mass M ref of the cooling fluid within the cooling system.

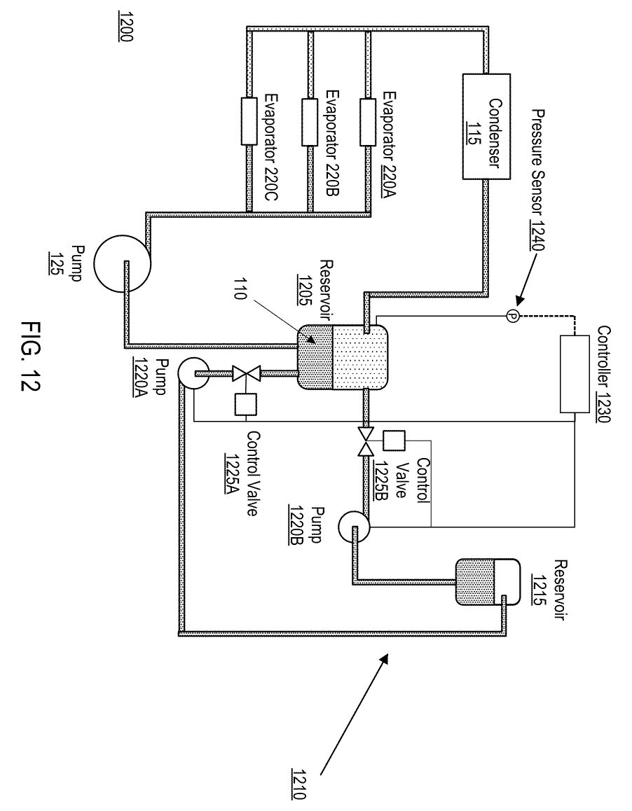

FIG. 12 sets forth an example pumped two-phase cooling system 1200 with a variable mass mechanism according to aspects of the present disclosure. The pumped two-phase cooling system 1200 includes a reservoir 1205 containing a cooling medium 110. The pumped two-phase cooling system 1200 further includes a condenser 115, multiple evaporators 220A, 220B, and 220C connected in parallel for cooling one or more electronic devices (not shown), and a pump 125 arranged in the manner described with respect to FIG. 6. An inlet of the pump 125 is coupled to an outlet of the reservoir 1205. The pumped two-phase cooling system 1200 includes a variable mass mechanism 1210 configured to adjust the mass of the cooling medium 110 contained with the reservoir 1205. The variable mass mechanism 1210 includes a secondary reservoir 1215, a first pump 1220A, a second pump 1220B, a first control valve 1225A, a second control valve 1225B, a controller 1230, and a pressure sensor 1240. The pressure sensor 1240 is configured to measure a pressure of the vapor phase of the reservoir 1205 and provide the pressure measurement to the controller 1230. As previously discussed, the pressure for a given specific volume defines how close the thermodynamic state of the cooling system is to the saturated liquid curve. Accordingly, the controller 1230 utilizes the pressure measurement to determine how M ref should be adjusted to achieve a desired specific volume v while V sys remains substantially constant. The variable mass mechanism 1210 is configured to add or remove the amount of cooling medium 110 within the reservoir 1205 to vary the mass of the cooling medium 110 in the reservoir 1205 in response to control signals from the controller 1230.

The pumped two-phase cooling system 1200 further includes a secondary reservoir 1215 holding additional quantities of the cooling medium 110. An output of the reservoir 1205 is coupled to the first control valve 1225A, and the first control valve 1225A is further coupled to the first pump 1220A. The first pump 1220A is further coupled to an inlet of the secondary reservoir 1215. An outlet of the secondary reservoir 1215 is coupled to the second pump 1220B, and the second pump 1220B is further coupled to the second control valve 1225B. The second control valve 1225B is further coupled to an inlet of the reservoir 1205. The operation of the first pump 1220A, the first control valve 1225A, the second pump 1220B, and the second control valve 1225B are under control of the controller 1230.

In response to the pressure measurement, the controller 1230 controls the variable mass mechanism 1210 to either increase or decrease the mass of the cooling medium 110 in the reservoir 1205. In order to decrease the mass of the cooling medium 110 in the reservoir 1205, the controller 1230 opens the first control valve 1225A, closes the second control valve 1225B, and activates the first pump 1220A to pump a portion of the cooling medium 110 from the reservoir 1205 into the secondary reservoir 1215 until the desired mass of cooling medium in the reservoir 1205 is achieved. When the desired amount of mass decrease is reached, the controller 1230 closes the first control valve 1225A and turns off the first pump 1220A. In order to increase the mass of the cooling medium 110 in the reservoir 1205, the controller 1230 closes the first control valve 1225A, opens the second control valve 1225B, and activates the second pump 1220B to pump fluid from the secondary reservoir 1215 into the reservoir 1205 until the desired mass of cooling medium 110 in the reservoir 1205 is reached. When the desired mass of cooling medium 110 is reached, the controller 1230 closes the second control valve 1225B and turns off the second pump 1220B.

By varying the mass of the cooling medium in the reservoir 1205, the variable mass mechanism 1210 changes the value of M ref, thus changing the specific volume v in accordance with the equation v= V sys/M ref to maintain the pumped two-phase cooling system 1200 within the desired thermodynamic state. For example, if it is desired to increase the value of the specific volume v, the controller 1230 controls the first pump 1220A, the first control valve 1225A, the second pump 1220B, and the second control valve 1225B to decrease the mass of the cooling medium 110 in the reservoir 1205. Conversely, if it is desired to decrease the value of the specific volume v, the controller 1230 controls the first pump 1220A, the first control valve 1225A, the second pump 1220B, and the second control valve 1225B to increase the mass of the cooling medium 110 in the reservoir 1205.

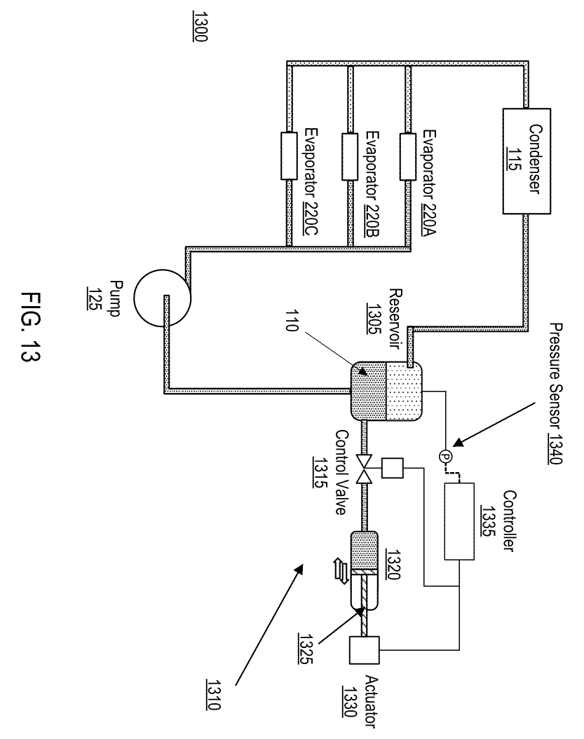

FIG. 13 sets forth another example pumped two-phase cooling system 1300 with a variable mass mechanism according to aspects of the present disclosure. The pumped two-phase cooling system 1300 includes a reservoir 1305 containing a cooling medium 110. The pumped two-phase cooling system 1300 further includes a condenser 115, multiple evaporators 220A, 220B, and 220C connected in parallel for cooling one or more electronic devices (not shown), and a pump 125 arranged in the manner described with respect to FIG. 6. An inlet of the pump 125 is coupled to an outlet of the reservoir 1305. The pumped two-phase cooling system 1300 includes a variable mass mechanism 1310 configured to adjust the mass of the cooling medium 110 contained with the reservoir 1305. The variable mass mechanism 1310 includes a control valve 1315, a secondary reservoir 1320, a piston mechanism 1325 coupled to the secondary reservoir 1320, an actuator 1330, a controller 1335, and a pressure sensor 1340. The pressure sensor 1340 is configured to measure a pressure of the vapor phase of the reservoir 1305 and provide the pressure measurement to the controller 1335. The variable mass mechanism 1310 is configured to add or remove the amount of cooling medium 110 within the reservoir 1305 to vary the mass of the cooling medium 110 in the reservoir 1305 in response to control signals from the controller 1335.

The secondary reservoir 1320 is configured to hold additional quantities of the cooling medium 110. An output of the reservoir 1305 is coupled to the control valve 1315, and the control valve 1315 is further coupled to the secondary reservoir 1320. The piston mechanism is coupled to the actuator 1330. The operation of the control valve 1315 and the actuator 1330 are under control of the controller 1335.

In response to the pressure measurement, the controller 1335 controls the variable mass mechanism 1310 to either increase or decrease the mass of the cooling medium 110 in the reservoir 1305. In order to decrease the mass of the cooling medium 110 in the reservoir 1305, the controller 1335 opens the control valve 1315, and causes the actuator 1330 to move the piston mechanism 1325 to draw a portion of the cooling medium 110 from the reservoir 1305 into the secondary reservoir 1320 until the desired mass of cooling medium in the reservoir 1205 is achieved. When the desired amount of mass decrease is reached, the controller 1335 closes the control valve 1315. In order to increase the mass of the cooling medium 110 in the reservoir 1305, the controller 1335 opens the control valve 1315 and causes the actuator 1330 to move the piston mechanism 1325 to push fluid from the secondary reservoir 1320 into the reservoir 1305 until the desired mass of cooling medium 110 in the reservoir 1305 is reached. When the desired mass of cooling medium 110 is reached, the controller 1335 closes the control valve 1315.

By varying the mass of the cooling medium in the reservoir 1305, the variable mass mechanism 1310 changes the value of M ref, thus changing the specific volume v in accordance with the equation v= V sys/M ref to maintain the pumped two-phase cooling system 1300 within the desired thermodynamic state. For example, if it is desired to increase the value of the specific volume v, the controller 1335 controls the control valve 1315 and the actuator 1330 to decrease the mass of the cooling medium 110 in the reservoir 1305. Conversely, if it is desired to decrease the value of the specific volume v, the controller 1335 controls the control valve 1315 and the actuator 1330 to increase the mass of the cooling medium 110 in the reservoir 1305.

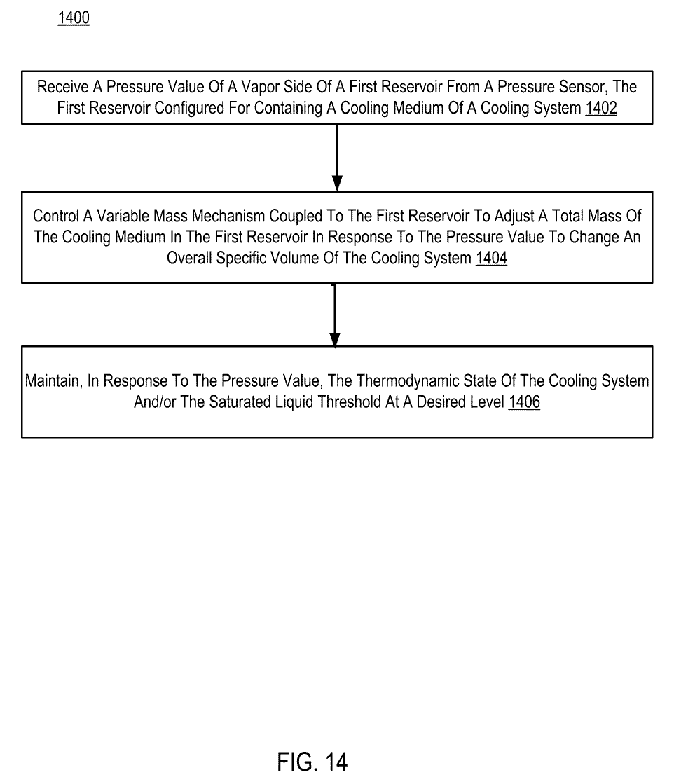

FIG. 14 sets forth a flowchart of another example process 1400 for facilitating cooling of one or more electronic devices in a cooling system according to aspects of the present disclosure. The example process 1400 includes receiving 1402 a pressure value of a vapor side of a reservoir from a pressure sensor. The reservoir is configured for containing a cooling medium of a cooling system. The example process further includes controlling 1404 a variable mass mechanism coupled to the reservoir to adjust a total mass of the cooling medium in the reservoir in response to the pressure value to change an overall specific volume of the cooling system. In an aspect, the change in the overall specific volume of the cooling medium of the cooling system adjusts a thermodynamic state of the cooling system. In another aspect, the variable mass mechanism includes a second reservoir configured to hold an additional amount of the cooling medium.

In another aspect, moving a portion of the cooling medium from the second reservoir to the first reservoir decreases the overall specific volume of the cooling system. In another aspect, moving a portion of the cooling medium from the first reservoir to the second reservoir increases the overall specific volume of the cooling system. In an aspect, the example process 1400 optionally includes maintaining 1406, in response to the pressure value, the thermodynamic state of the cooling system and/or a saturated liquid threshold at a desired level.

In another aspect, a cooling system may be provided with both a variable volume mechanism and a variable mass mechanism to adjust both the volume and mass of a cooling medium to produce a desired specific volume v of the cooling system in accordance with the equation v= V sys/M ref.

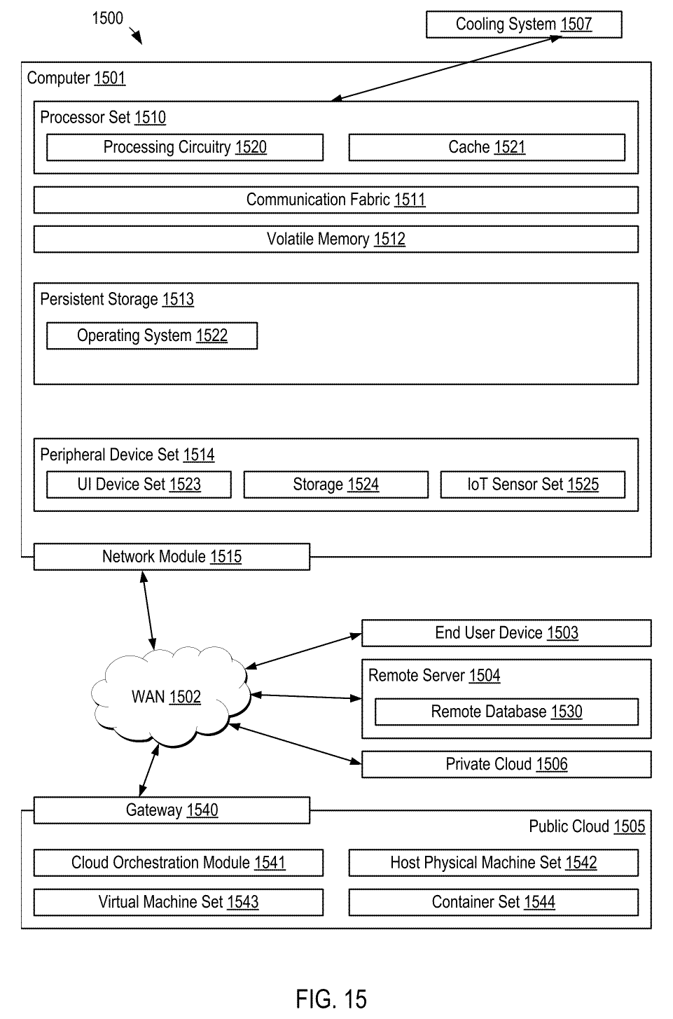

FIG. 15 sets forth an example computing environment according to aspects of the present disclosure. Computing environment 1500 contains an example of an environment for the execution of at least some of the computer code involved in performing the various methods described herein, such as a cooling system 1507 configured for adjusting a specific volume v of the cooling system 1507 in order to cool one or more components of the computing environment as described herein with respect to various embodiments. In particular implementations, the cooling system 1507 is mounted within a rack. In addition to cooling system 1507, computing environment 1500 includes, for example, computer 1501, wide area network (WAN) 1502, end user device (EUD) 1503, remote server 1504, public cloud 1505, and private cloud 1506. In this embodiment, computer 1501 includes processor set 1510 (including processing circuitry 1520 and cache 1521), communication fabric 1511, volatile memory 1512, persistent storage 1513 (including operating system 1522 and cooling system 1507, as identified above), peripheral device set 1514 (including user interface (UI) device set 1523, storage 1524, and Internet of Things (IoT) sensor set 1525), and network module 1515. Remote server 1504 includes remote database 1530. Public cloud 1505 includes gateway 1540, cloud orchestration module 1541, host physical machine set 1542, virtual machine set 1543, and container set 1544.

Computer 1501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1530. As is well understood in the art of computer technology, and depending upon the technology, performance of a computer-implemented method may be distributed among multiple computers and/or between multiple locations. On the other hand, in this presentation of computing environment 1500, detailed discussion is focused on a single computer, specifically computer 1501, to keep the presentation as simple as possible. Computer 1501 may be located in a cloud, even though it is not shown in a cloud in FIG. 15. On the other hand, computer 1501 is not required to be in a cloud except to any extent as may be affirmatively indicated.

Processor set 1510 includes one, or more, computer processors of any type now known or to be developed in the future. Processing circuitry 1520 may be distributed over multiple packages, for example, multiple, coordinated integrated circuit chips. Processing circuitry 1520 may implement multiple processor threads and/or multiple processor cores. Cache 1521 is memory that is located in the processor chip package(s) and is typically used for data or code that should be available for rapid access by the threads or cores running on processor set 1510. Cache memories are typically organized into multiple levels depending upon relative proximity to the processing circuitry. Alternatively, some, or all, of the cache for the processor set may be located “off chip.” In some computing environments, processor set 1510 may be designed for working with qubits and performing quantum computing.

Computer readable program instructions are typically loaded onto computer 1501 to cause a series of operational steps to be performed by processor set 1510 of computer 1501 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 1521 and the other storage media discussed below. The program instructions, and associated data, are accessed by processor set 1510 to control and direct performance of the computer-implemented methods. In computing environment 1500, at least some of the instructions for performing the computer-implemented methods may be stored in persistent storage 1513.

Communication fabric 1511 is the signal conduction path that allows the various components of computer 1501 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

Volatile memory 1512 is any type of volatile memory now known or to be developed in the future. Examples include dynamic type random access memory (RAM) or static type RAM. Typically, volatile memory 1512 is characterized by random access, but this is not required unless affirmatively indicated. In computer 1501, the volatile memory 1512 is located in a single package and is internal to computer 1501, but, alternatively or additionally, the volatile memory may be distributed over multiple packages and/or located externally with respect to computer 1501.

Persistent storage 1513 is any form of non-volatile storage for computers that is now known or to be developed in the future. The non-volatility of this storage means that the stored data is maintained regardless of whether power is being supplied to computer 1501 and/or directly to persistent storage 1513. Persistent storage 1513 may be a read only memory (ROM), but typically at least a portion of the persistent storage allows writing of data, deletion of data and re-writing of data. Some familiar forms of persistent storage include magnetic disks and solid state storage devices. Operating system 1522 may take several forms, such as various known proprietary operating systems or open source Portable Operating System Interface-type operating systems that employ a kernel. The code included in persistent storage 1513 typically includes at least some of the computer code involved in performing the computer-implemented methods described herein.

Peripheral device set 1514 includes the set of peripheral devices of computer 1501. Data communication connections between the peripheral devices and the other components of computer 1501 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1523 may include components such as a display screen, speaker, microphone, wearable devices (such as goggles and smart watches), keyboard, mouse, printer, touchpad, game controllers, and haptic devices. Storage 1524 is external storage, such as an external hard drive, or insertable storage, such as an SD card. Storage 1524 may be persistent and/or volatile. In some embodiments, storage 1524 may take the form of a quantum computing storage device for storing data in the form of qubits. In embodiments where computer 1501 is required to have a large amount of storage (for example, where computer 1501 locally stores and manages a large database), this storage may be provided by peripheral storage devices designed for storing very large amounts of data, such as a storage area network (SAN) that is shared by multiple, geographically distributed computers. IoT sensor set 1525 is made up of sensors that can be used in Internet of Things applications. For example, one sensor may be a thermometer and another sensor may be a motion detector.

Network module 1515 is the collection of computer software, hardware, and firmware that allows computer 1501 to communicate with other computers through WAN 1502. Network module 1515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1515 are performed on the same physical hardware device. In other embodiments (for example, embodiments that utilize software-defined networking (SDN)), the control functions and the forwarding functions of network module 1515 are performed on physically separate devices, such that the control functions manage several different network hardware devices. Computer readable program instructions for performing the computer-implemented methods can typically be downloaded to computer 1501 from an external computer or external storage device through a network adapter card or network interface included in network module 1515.

WAN 1502 is any wide area network (for example, the internet) capable of communicating computer data over non-local distances by any technology for communicating computer data, now known or to be developed in the future. In some embodiments, the WAN 1502 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1503 is any computer system that is used and controlled by an end user (for example, a customer of an enterprise that operates computer 1501), and may take any of the forms discussed above in connection with computer 1501. EUD 1503 typically receives helpful and useful data from the operations of computer 1501. For example, in a hypothetical case where computer 1501 is designed to provide a recommendation to an end user, this recommendation would typically be communicated from network module 1515 of computer 1501 through WAN 1502 to EUD 1503. In this way, EUD 1503 can display, or otherwise present, the recommendation to an end user. In some embodiments, EUD 1503 may be a client device, such as thin client, heavy client, mainframe computer, desktop computer and so on.

Remote server 1504 is any computer system that serves at least some data and/or functionality to computer 1501. Remote server 1504 may be controlled and used by the same entity that operates computer 1501. Remote server 1504 represents the machine(s) that collect and store helpful and useful data for use by other computers, such as computer 1501. For example, in a hypothetical case where computer 1501 is designed and programmed to provide a recommendation based on historical data, then this historical data may be provided to computer 1501 from remote database 1530 of remote server 1504.

Public cloud 1505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1505 is performed by the computer hardware and/or software of cloud orchestration module 1541. The computing resources provided by public cloud 1505 are typically implemented by virtual computing environments that run on various computers making up the computers of host physical machine set 1542, which is the universe of physical computers in and/or available to public cloud 1505. The virtual computing environments (VCEs) typically take the form of virtual machines from virtual machine set 1543 and/or containers from container set 1544. It is understood that these VCEs may be stored as images and may be transferred among and between the various physical machine hosts, either as images or after instantiation of the VCE. Cloud orchestration module 1541 manages the transfer and storage of images, deploys new instantiations of VCEs and manages active instantiations of VCE deployments. Gateway 1540 is the collection of computer software, hardware, and firmware that allows public cloud 1505 to communicate through WAN 1502.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1506 is similar to public cloud 1505, except that the computing resources are only available for use by a single enterprise. While private cloud 1506 is depicted as being in communication with WAN 1502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1505 and private cloud 1506 are both part of a larger hybrid cloud.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus for facilitating cooling of one or more electronic devices in a cooling system, the apparatus comprising:
a first reservoir configured for containing a cooling medium of a cooling system;
a variable mass mechanism coupled to the first reservoir;
a pressure sensor for sensing a pressure value of a vapor side of the first reservoir; and
a controller coupled to the pressure sensor and the variable mass mechanism, the controller configured to control the variable mass mechanism to adjust a total mass of the cooling medium in the first reservoir in response to the pressure value to change an overall specific volume of the cooling system.

2. The apparatus of claim 1, wherein the change in the overall specific volume of the cooling medium of the cooling system adjusts a thermodynamic state of the cooling system.

3. The apparatus of claim 2, wherein the controller is further configured to maintain, in response to the pressure value, the thermodynamic state of the cooling system.

4. The apparatus of claim 1, wherein the variable mass mechanism comprises a second reservoir configured to hold an additional amount of the cooling medium.

5. The apparatus of claim 4, wherein the controller is configured to move a portion of the cooling medium from the second reservoir to the first reservoir to decrease the overall specific volume of the cooling system.

6. The apparatus of claim 4, wherein the controller is configured to move a portion of the cooling medium from the first reservoir to the second reservoir to increase the overall specific volume of the cooling system.

7. The apparatus of claim 4, further comprising a piston within the second reservoir, the piston configured to move a portion of the cooling medium between the first reservoir and the second reservoir.

8. The apparatus of claim 7, further comprising an actuator mechanically coupled to the piston, the actuator configured to move the piston within the second reservoir in response to a signal from the controller.

9. The apparatus of claim 4, further comprising:
a first pump coupled to an outlet of the second reservoir; and
a first control valve coupled between the first pump and an inlet of the first reservoir.

10. The apparatus of claim 9, further comprising:
a second control valve coupled to an outlet of the first reservoir; and
a second pump coupled between the second control valve and the second reservoir.

11. The apparatus of claim 10, wherein the controller is configured to control the first pump, the first control valve, the second pump, and the second control valve to a portion of the cooling medium between the first reservoir and the second reservoir.

12. A method comprising:
receiving a pressure value of a vapor side of a first reservoir from a pressure sensor, the first reservoir configured for containing a cooling medium of a cooling system; and
controlling a variable mass mechanism coupled to the first reservoir to adjust a total mass of the cooling medium in the first reservoir in response to the pressure value to change an overall specific volume of the cooling system.

13. The method of claim 12, wherein the change in the overall specific volume of the cooling medium of the cooling system adjusts a thermodynamic state of the cooling system.

14. The method of claim 12, further comprising maintaining, in response to the pressure value, the thermodynamic state of the cooling system.

15. The method of claim 12, wherein the variable mass mechanism comprises a second reservoir configured to hold an additional amount of the cooling medium.

16. The method of claim 15, further comprising moving a portion of the cooling medium from the second reservoir to the first reservoir to decrease the overall specific volume of the cooling system.

17. The apparatus of claim 15, further comprising moving a portion of the cooling medium from the first reservoir to the second reservoir to increase the overall specific volume of the cooling system.

18. A system comprising:
a condenser;
an evaporator coupled to the condenser;
a first reservoir having an inlet coupled to the condenser and an outlet coupled to the evaporator through a pump, the first reservoir configured for containing a cooling medium of a cooling system;
a variable mass mechanism coupled to the first reservoir;
a pressure sensor for sensing a pressure value of a vapor side of the first reservoir; and
a controller coupled to the pressure sensor and the variable mass mechanism, the controller configured to control the variable mass mechanism to adjust a total mass of the cooling medium in the first reservoir in response to the pressure value to change an overall specific volume of the cooling system.

19. The system of claim 18, wherein the evaporator is configured to be thermally coupled to an electronic device.

20. The system of claim 18, wherein the change in the overall specific volume of the cooling medium of the cooling system adjusts a thermodynamic state of the cooling system.
